(19) United States
(12) Patent Application Publication
(10) Pub. No.: US 2012/0108079 A1
(43) Pub. Date: May 3, 2012

(54) Atomic Layer Deposition Film With Tunable Refractive Index And Absorption Coefficient And Methods Of Making

(75) Inventor: Maitreyee Mahajani, Saratoga, CA (US)

(73) Assignee: Applied Materials, Inc., Santa Clara, CA (US)

(21) Appl. No.: 13/192,993

(22) Filed: Jul. 28, 2011

Related U.S. Application Data
(60) Provisional application No. 61/408,028, filed on Oct. 29, 2010.

(51) Int. Cl. H01L 21/316

(52) U.S. Cl. 438/788; 257/E21.271

(57) ABSTRACT

Atomic layer deposition methods of forming one or more of a mixed silicon oxide/silicon nitride film or a mixed silicon oxide/silicon film are described in which the substrate is exposed sequentially to a first reactant gas comprising a silicon species and a second reactant gas comprising an oxygen species to form at least a partial layer of silicon oxide on the substrate during a first atomic layer deposition process. The substrate is then exposed sequentially to a third reactant gas comprising a silicon species and a fourth reactant gas comprising a species sufficient to form at least a partial layer of one or more of silicon nitride or silicon on the substrate during a second atomic layer deposition process. The process can be repeated multiple times to deposit one or more of a mixed silicon oxide/silicon nitride film and a mixed silicon oxide/silicon film.

### CROSS-REFERENCE TO RELATED APPLICATIONS

This application claims priority under 35 U.S.C. §119(e) to U.S. Provisional Application No. 61/408,028, filed Oct. 29, 2010.

### BACKGROUND

Embodiments of the invention generally relate to processes for the deposition of silicon oxynitride films. More specifically, embodiments of the invention relate to atomic layer deposition films, and methods of making such films, having mixed silicon oxide/silicon nitride films with tunable refractive indexes and absorption coefficients.

During an atomic layer deposition (ALD) process, reactant gases are sequentially introduced into a process chamber containing a substrate. Generally, a first reactant is introduced into a process chamber and is adsorbed onto the substrate surface. A second reactant is then introduced into the process chamber and reacts with the first reactant to form a deposited material. A purge step may be carried out between the delivery of each reactant gas to ensure that the only reactions that occur are on the substrate surface. The purge step may be a continuous purge with a carrier gas or a pulse purge between the delivery of the reactant gases.

Atomic layer deposition of silicon oxide (SiO₂) and silicon nitride (SiN) films are being explored for several applications. One such application is the use of low temperature ALD oxide for Self-Aligned Double Patterning (SADP). In a typical double patterning process, the oxide films are deposited at less than about 100° C. over a photoresist. The refractive index (n) and absorption coefficient (k) values of the deposited oxide need to be tuned to match those of the photoresist. Tuning these values in the oxide film can be complicated and time consuming. Therefore, is a need in the art for films and methods of making films with tunable n and k values.

### SUMMARY

One or more embodiments of the invention are directed to methods for forming a film on a substrate, the film having a refractive index and an absorption coefficient. A substrate is exposed sequentially to a first reactant gas comprising a first species including one or more of silicon, oxygen and nitrogen and a second reactant gas comprising a second species to form a first partial layer on the substrate during a first atomic layer deposition process. In detailed embodiments the second species is sufficient to form a silicon oxide film on the surface of the substrate. The substrate is also exposed sequentially to a third reactant gas comprising a third species including one or more of silicon, oxygen and nitrogen and a fourth reactant gas comprising a fourth species sufficient to form a second partial layer on the substrate during a second atomic layer deposition process. In specific embodiments, the fourth species is sufficient to form one or more of a silicon nitride or silicon film on the substrate. The first atomic layer deposition process and the second atomic layer deposition process are sequentially repeated to form a mixed film comprising the first partial layer and the second partial layer, wherein one or more of the refractive index and the absorption coefficient can be altered by changing a ratio of the first partial layer to the second partial layer. Either the first atomic layer deposition process or the second atomic layer deposition process can be performed first. In detailed embodiments, the mixed film comprises silicon oxide and silicon nitride and the refractive index of the mixed silicon oxide/silicon nitride film is in a range of about 1.6 to about 1.7.

In one or more embodiments, the first species comprises one or more of silane, disilane and a halide of silane. As used in this specification and the appended claims, the term “halide of silane” means a silicon compound with one or more halogen attached thereto. Examples of halides of silane include, but are not limited to, SiH₃Cl, SiH₂Br₂, SiHF₃, SiCl₄, Si₂H₅Cl, Si₂H₄Cl₂, Si₂H₃Cl₃, Si₂H₂Cl₄, Si₂HCl₅, Si₂Cl₆ and combinations with various halogen atoms. In detailed embodiments, the second species comprises water.

In detailed embodiments, the third species comprises one or more of silane, disilane and a halide of silane. In specific embodiments, the fourth species comprises one or more of nitrogen and a reducing agent or oxidizing agent sufficient to form silicon. For example, where the third species contains silicon of the +3 oxidation state, then a suitable reducing agent might be used, including, but not limited to silicon species with negative oxidation states.

One or more embodiments of the invention are directed to methods for forming a film on a substrate. The methods comprise exposing the substrate sequentially to a first reactant gas comprising a silicon species and a second reactant gas comprising an oxygen species to form at least a partial layer of silicon oxide on the substrate during a first atomic layer deposition process. The substrate is exposed sequentially to a third reactant gas comprising a silicon species and a fourth reactant gas comprising a nitrogen species to form at least a partial layer of silicon nitride the substrate during a second atomic layer deposition process. The first atomic layer deposition process and the second atomic layer deposition process are repeated sequentially to form a mixed silicon oxide/silicon nitride film having a refractive index and absorption coefficient. In detailed embodiments, either the first atomic layer deposition process or the second atomic layer deposition process occurs first.

In some embodiments, the refractive index and absorption coefficient are controlled by a ratio of the silicon oxide and silicon nitride present in the mixed silicon oxide/silicon nitride film. In specific embodiments, the refractive index of the mixed silicon oxide/silicon nitride film is in a range of about 1.6 to about 1.7.

The silicon species in the first reactant gas and the third reactant gas can be the same or different and can selected from various silicon compounds. In detailed embodiments, the silicon species in the first reactant gas comprises hexachlorodisilane. In specific embodiments, the silicon species of the third reactant gas comprises disilane.

In detailed embodiments, the oxygen species in the second reactant gas comprises water. In some embodiments, the nitrogen species of the fourth reactant gas comprises nitrogen. In specific embodiments, the nitrogen is a plasma.

The second atomic layer deposition process in some embodiments is performed in a process chamber and the plasma is generated remotely from the process chamber. In various embodiments, the second atomic layer deposition process is performed in a process chamber and the plasma is generated within the process chamber.

In detailed embodiments, the first atomic layer deposition process occurs at a temperature in a range of about 20° C. to about 150° C. In specific embodiments, the second atomic layer deposition process occurs at a temperature in a range of about 75° C. to about 500° C.

Some embodiments further comprise exposing the substrate to a purge gas during a purge process. In detailed embodiments, the purge process occurs after one or more of the first atomic layer deposition process and the second atomic layer deposition process. The purge gas of one or more embodiments is selected from an inert gas. In detailed embodiments, the inert gas is selected from nitrogen, argon and combinations thereof.

The mixed silicon oxide/silicon nitride film of some embodiments has a thickness up to about 500 Å. In specific embodiments, the first atomic layer deposition process forms less than a full monolayer of silicon oxide and the second atomic layer deposition process forms less than a full monolayer of silicon nitride creating a mixture of partial monolayers without distinct layers of silicon oxide and silicon nitride.

Additional embodiments of the invention are directed to methods of forming one or more of a mixed silicon oxide/silicon nitride film or silicon oxide/silicon film on a substrate. A substrate is disposed within a processing chamber. A first atomic layer deposition process is performed. The first atomic layer deposition process comprises flowing hexachlorodisilane gas and, optionally, a catalyst (e.g., pyridine or ammonia) to the substrate within the chamber under conditions which form a partial monolayer on the substrate, the partial monolayer comprising silicon terminated with chlorine. The hexahclorodisilane is purged and water vapor and, optionally, a catalyst is flowed to the substrate within the chamber under conditions which form a partial monolayer on the substrate comprising silicon oxide. The water vapor is purged and a second atomic layer deposition process is performed. The second atomic layer deposition process comprises flowing disilane gas to the substrate within the chamber under conditions which form a partial monolayer comprising silicon. The disilane is purged and a nitrogen plasma is flowed to the substrate within the chamber under conditions to form a partial monolayer comprising silicon nitride. The plasma is purged and the first atomic layer deposition process and the second atomic layer deposition process are repeated.

Further embodiments of the invention are directed to methods for forming a film on a substrate, the film having a refractive index and an absorption coefficient. A substrate is exposed sequentially to a first reactant gas comprising a first species and a second reactant gas comprising a second species to form a first partial layer on the substrate during a first atomic layer deposition process. The substrate is exposed sequentially to a third reactant gas comprising a third species and a fourth reactant gas comprising a fourth species to form a second partial layer on the substrate during a second atomic layer deposition process. The first atomic layer deposition process and the second atomic layer deposition process are repeated to form a mixed film comprising the first partial layer and the second partial layer, wherein one or more of the refractive index and the absorption coefficient can be altered by changing a ratio of the first partial layer to the second partial layer.

### BRIEF DESCRIPTION OF THE DRAWINGS

So that the manner in which the exemplary embodiments of the present invention are attained and can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIGS. 1A through 1E show a partial view of a substrate with a mixed silicon oxide/silicon nitride film in accordance with one or more embodiments of the invention.

It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As used in this specification and the appended claims, the term “purge” is used to mean any process in which the contents of a system are removed. Purging can mean that the contents (e.g., a gaseous reactant) are removed by being replaced with another gas (e.g., an inert gas) or removed by introducing a vacuum (or partial vacuum) to the system.

Embodiments of the invention are directed to methods to achieve tunability of the refractive index and absorption coefficient of a film in a single chamber. The n and k values can range from that of pure film of a first material (e.g., SiO₂ (about 1.46)) to that of a pure film of a second material (e.g., SiN (about 1.94) or Si (about 3.42)). A film deposited in a single chamber with flexibility to adjust n and k values using process parameters is desired. While various mixed films can be generated with the methods, the description below is specific to silicon oxide and silicon nitride mixed films.

Several chemistries are available to deposit ALD SiO₂ at low temperature as well as at high temperatures. Similarly, there are several chemistries for ALD SiN and ALD Si at various temperatures. In one or more embodiments of the invention, chemistries for each desired deposition film are connected to an ALD chamber. The desired film is deposited as a microlaminate of SiO₂ and SiN (or Si) where each laminate is on the order of a few monolayers (1-15 Å). By alternating different ratio SiO₂:SiN laminates or SiO₂:Si laminates, a film can be deposited with different n and k values which can be tuned to more closely match the n and k values of the photoresist.

Atomic layer deposition is a deposition technique used to form thin films on a substrate, for example, a semiconductor substrate and may be used to form features in the manufacturing process of circuit devices. A thin film is grown layer by layer by exposing a surface, or portion of a surface, of the substrate disposed in a process chamber to alternating pulses of reactants or chemical precursors, each of which undergoes a reaction, generally providing controlled film thickness. Each reactant pulse provides an additional atomic layer to previously deposited layers. In an embodiment, a film growth cycle generally consists of two pulses, each pulse being separated by a purge. In temporally separated ALD processing, the entire process chamber can be purged with an inert gas to remove the reactant or precursor material. When second reactant or precursor material is pulsed into the reactor, the second reactant or precursor material reacts with the precursor material on the wafer surface. The reactor is purged again with an inert gas. In spatially separated processing, portions of the substrate are sequentially exposed to the first reactant and the second reactant without allowing the gaseous reactants to mix. In spatial ALD, several portions of the substrate are exposed simultaneously to the first reactant and other portions of the substrate are exposed simultaneously to the second reactant. The substrate, or gas distribution plate, is moved so that the portions exposed to the first reactant are then exposed to the second reactant, and vice versa. Commonly assigned U.S. Pat. No. 6,821,563 describes a spatial ALD process in detail. In an ALD manufacturing process, the thickness of the deposited film is controlled by the number of cycles.

Atomic layer deposition may also be referred to as cyclical deposition, referring to the sequential introduction of two or more reactive compounds to deposit a layer of material on a substrate surface. The two or more reactive compounds are alternatively introduced into a reaction zone or process region of a processing chamber. The reactive compounds may be in a state of gas, plasma, vapor, fluid or other state of matter useful for a vapor deposition process. Usually, each reactive compound is separated by a time delay to allow each compound to adhere, adsorb, absorb and/or react on the substrate surface. In one aspect, a first precursor or compound A is pulsed into the reaction zone followed by a first time delay. Next, a second precursor or compound B is pulsed into the reaction zone followed by a second delay. Compound A and compound B react to form a deposited material. During each time delay, a purge gas is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film thickness of the deposited material is formed on the substrate surface. In either scenario, the ALD process of pulsing compound A, purge gas, pulsing compound B and purge gas is a cycle. A deposition gas or a process gas as used herein refers to a single gas, multiple gases, a gas containing a plasma, combinations of gas(es) and/or plasma(s). A deposition gas may contain at least one reactive compound for a vapor deposition process. The reactive compounds may be in a state of gas, plasma, vapor, fluid during the vapor deposition process. Also, a process may contain a purge gas or a carrier gas and not contain a reactive compound.

A “substrate surface,” as used herein, refers to any substrate, part of a substrate, or material surface or part of a material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride. Substrates may have various dimensions, such as 200 mm or 300 mm diameter wafers, as well as, rectangular or square panes. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers and patterned or non-patterned wafers. Substrates may be exposed to a pretreatment process to polish, etch, reduce, oxidize, hydroxylate, anneal and/or bake the substrate surface.

Embodiments of the invention provide methods for depositing or forming a mixed silicon oxide/silicon nitride film on a substrate during a vapor deposition process, such as atomic layer deposition or plasma-enhanced ALD (PE-ALD). A processing chamber is configured to expose the substrate to a sequence of gases and/or plasmas during the deposition process.

The methods, also referred to as processes, include sequentially exposing a substrate, or portion of a substrate, to various deposition gases containing chemical precursors or reactants including a first reactant gas and a second reactant gas. In detailed embodiments, the first reactant gas comprises a silicon species and the second reactant gas comprising an oxygen species. The first reactant gas and second reactant gas form at least a partial layer of silicon oxide on the substrate during a first atomic layer deposition process. The substrate is also exposed, sequentially, to a third reactant gas and a fourth reactant gas. In specific embodiments, the third reactant gas comprises a silicon species and the fourth reactant gas comprises a nitrogen species sufficient for SiN formation or a reducing agent or oxidizing agent sufficient for Si formation. The third reactant gas and fourth reactant gases forming at least a partial layer of silicon nitride or silicon on the substrate during a second atomic layer deposition process. The first atomic layer deposition process and the second atomic layer deposition process are repeated sequentially to form a mixed silicon oxide/silicon nitride film having a desired thickness. Skilled artisans will understand that the first atomic layer deposition process can be repeated multiple times before the second atomic layer deposition process, and that the second atomic layer deposition process can be repeated multiple times before the first atomic layer deposition process, and that either process can be performed first. In other words, the initial film can be either a SiO₂ layer, an SiN layer or a Si layer.

According to one or more embodiments of the invention, the mixed silicon oxide/silicon nitride film or silicon oxide/silicon film has a refractive index and an absorption coefficient which can be controlled by adjusting the ratio of the first partial layer (i.e., the at least partial layer deposited during the first atomic layer deposition process) and the second partial layer (i.e., the at least partial layer deposited during the second atomic layer deposition process). In specific embodiments, one or more of the refractive index and the absorption coefficient are controlled by the ratio of silicon oxide and silicon nitride (or silicon) present in a mixed silicon oxide/nitride (or silicon oxide/silicon) film. Both the refractive index and the absorption coefficient can range from that of pure silicon oxide to that of pure silicon nitride or pure silicon. In detailed embodiments, the refractive index of a mixed silicon oxide/silicon nitride film is in the range of about 1.5 to about 1.8. In specific embodiments, the refractive index of a mixed silicon oxide/silicon nitride film is in the range of about 1.6 to about 1.7. In embodiments where the first partial layer comprises a compound other than silicon oxide and/or the second partial layer comprises a compound other than silicon nitride (e.g., silicon), the range of the refractive indexes and absorption coefficients would be from those of the first partial layer component to those of the second partial layer component.

The silicon species in the first reactant gas and the third reactant gas can be any suitable silicon-containing gas known to the skilled artisan. Suitable silicon-containing species include, but are not limited to, silicon tetrachloride, disilane, hexachlorodisilane, silane, trisilane, trisilylamine (TSA), bis(t-butylamino)silane (BTBAS), bis-diethylaminosilane (BDEAS), bis-dimethylaminosilane (BDMAS), tetrakis(diethylamino)silane (TDEAS) and mixtures thereof. In one or more embodiments, the first species comprises one or more of silane, disilane and a halide of silane. As used in this specification and the appended claims, the term “halide of silane” means a silicon compound with one or more halogen attached thereto. Examples of halides of silane include, but are not limited to, SiH₃Cl, SiH₂Br₂, SiHF₃, SiCl₄, Si₂H₅Cl, Si₂H₄Cl₂, Si₂H₃Cl₃, Si₂H₂Cl₄, Si₂HCl₅, Si₂Cl₆ and combinations with various halogen atoms. In specific embodiments, the silicon-containing species in the first reactant gas is hexachlorodisilane. In detailed embodiments, the silicon-containing species of the third reactant gas comprises disilane.

The oxygen species in the second reactant gas can be any suitable oxygen-containing compound known to the skilled artisan. Suitable oxygen-containing compounds include, but are not limited to, molecular oxygen, ozone, alcohols, N₂O and water vapor. In specific embodiments, the oxygen species in the second reactant gas comprises water.

The nitrogen species in the fourth reactant gas can be any suitable nitrogen-containing compound known to the skilled artisan. Suitable nitrogen containing species include, but are not limited to, molecular nitrogen including both ground state and energized nitrogen (i.e., as found in a nitrogen plasma), ammonia and ammonium species. In specific embodiments, the nitrogen species of the fourth reactant gas comprises nitrogen. In specific embodiments, the nitrogen species of the fourth reactant gas comprises a nitrogen plasma. The nitrogen plasma can be generated directly within the process chamber or can be remotely generated and introduced to the process chamber.

The reactants are typically in vapor or gas form and may be delivered with a carrier gas, a purge gas, a deposition gas, or other process gas and may contain nitrogen, hydrogen, argon, neon, helium, or combinations thereof. Plasmas may be useful for depositing, forming, annealing, treating, or other processing of the materials described herein. Suitable plasmas include, but are not limited to, nitrogen plasmas, which may contain nitrogen, hydrogen, argon, neon, helium, or combinations thereof.

The first atomic layer deposition process results in the formation of silicon oxide (SiO₂) on the substrate. The second atomic layer deposition process results in the formation of silicon nitride (SiN) or silicon on the substrate. Either of these processes can be performed first and each can be repeated before performing the other process. In detailed embodiments, the first atomic layer deposition process occurs at a temperature in the range of about 20° C. to about 150° C. In some embodiments, the second atomic layer deposition process occurs at a temperature in the range of about 75° C. to about 500° C. Additionally, a purge process may occur after one or more of the first atomic layer deposition process and the second atomic layer deposition process. The purge gas of detailed embodiments is selected from an inert gas. In specific embodiments, the inert gas is selected from nitrogen, argon and combinations thereof. Although a temporally separated deposition is described, it will be understood by those skilled in the art that a spatially separated deposition can be employed. The scope of the invention should not limited to any particular type of ALD process.

Each of the partial layers of silicon oxide and silicon nitride (or silicon) can have a varying range of thickness from less than a full monolayer thick (˜1 Å) to about 25 Å. However, without being bound by any particular theory of operation, it is believed that layer thicknesses greater than about 15 Å may result in discrete sublayers which are much more difficult to control the refractive index and absorption coefficient. In detailed embodiments, each of the silicon oxide and silicon nitride layers can have a thickness in the range of about 1 Å to about 15 Å. The total thickness of the mixed silicon oxide/silicon nitride film, after deposition of all partial layers, may be up to about 750 Å. In detailed embodiments, the total thickness of the silicon oxide/silicon nitride film is in the range of about 10 A to about 500 A. In specific embodiments, the total thickness of the silicon oxide/silicon nitride film is in the range of about 15 Å to about 400 Å, or in the range of about 20 Å to about 300 Å, or in the range of about 25 Å to about 200 Å, or in the range of about 30 Å to about 100 Å. In various embodiments, the total thickness of the mixed silicon oxide/silicon nitride film is less than about 500 Å, 400 Å, 300 Å, 200 Å, 100 Å, 75 Å or 50 Å.

In some embodiments, one or more of the silicon oxide and silicon nitride layers are less than full monolayers. This may result in a more random mixture of silicon oxide and silicon nitride than if full monolayers of silicon oxide and/or silicon nitride are formed. In specific embodiments, the first atomic layer deposition process forms less than a full monolayer of silicon oxide and the second atomic layer deposition process forms less than a full monolayer of silicon nitride creating a mixture of partial monolayers without distinct layers of silicon oxide and silicon nitride.

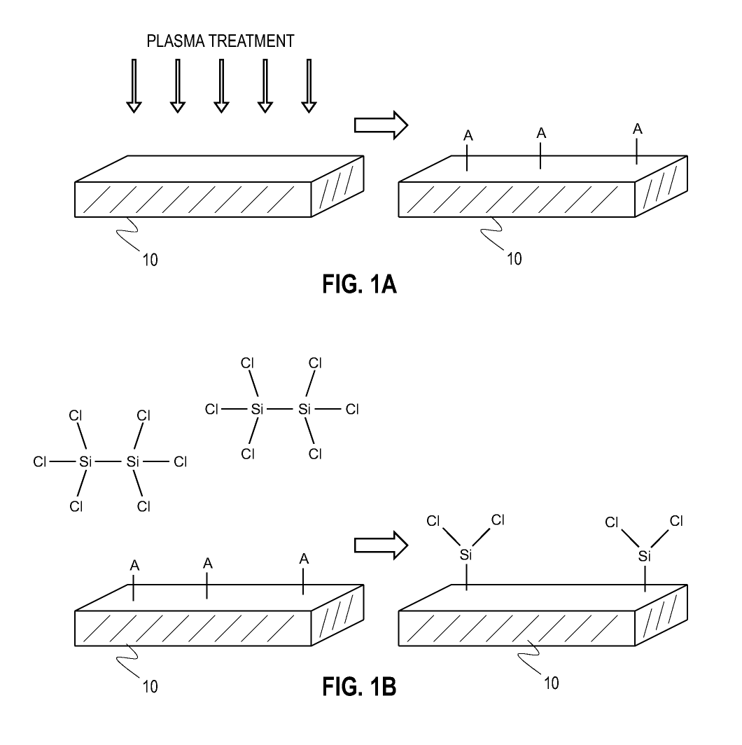

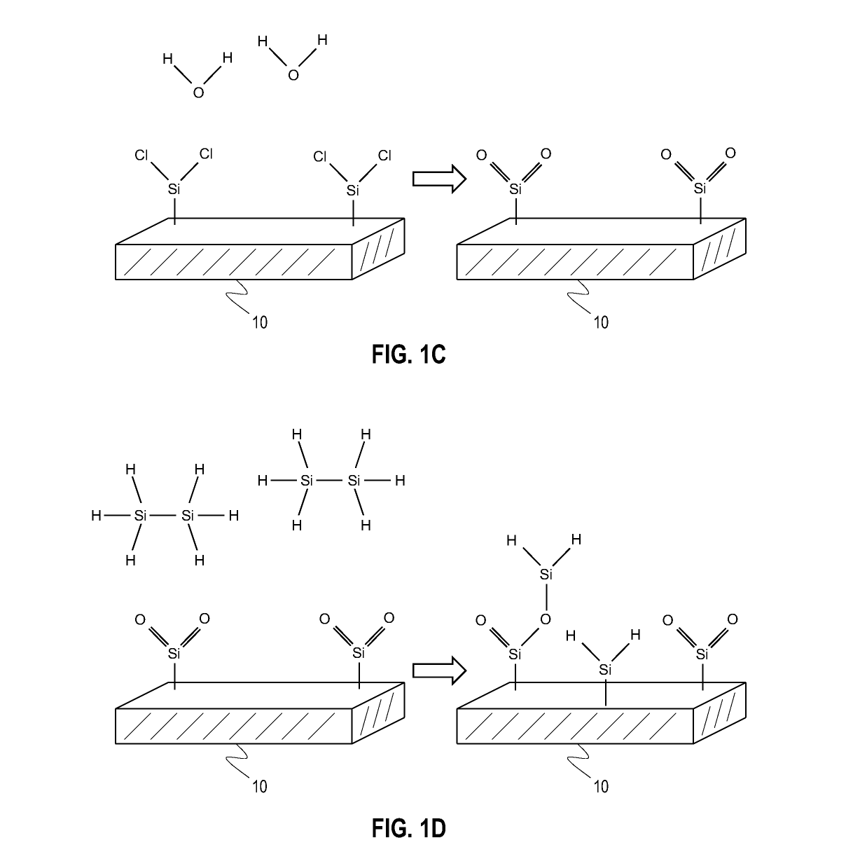

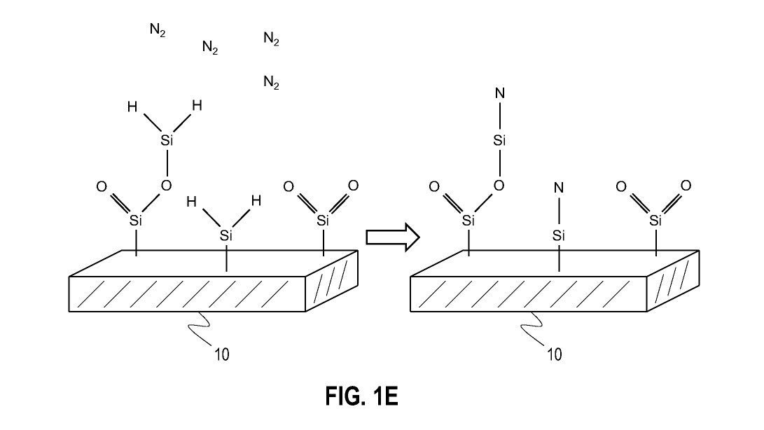

FIG. 1 illustrates a detailed embodiment of a method for forming a mixed silicon oxide/silicon nitride film on a substrate 10. In FIG. 1A, a substrate 10 is disposed within a processing chamber (not shown). The surface of the substrate 10 is “activated” by exposing the substrate to a plasma treatment. Plasma treatment is merely one way of creating active sites on the substrate and should not be taken as limiting the scope of the invention. The active sites (denoted with an ‘A’ in the right side of FIG. 1A) are available for further reactions in the ALD process.

After creating active sites on the substrate 10, a first atomic layer deposition process is performed on the substrate. The first atomic layer deposition process is illustrated by FIGS. 1B and 1C. A silicon containing gas, shown as hexachlorodisilane (HCD) in FIG. 1B, is flowed to the substrate 10 within the chamber under conditions which form a partial monolayer on the substrate. Although not shown in the Figures, one or more catalysts (e.g., pyridine and ammonia) may be included in the deposition processes. The by-products, catalysts and partial reactions have been omitted from the drawings for purposes of clarity. The partial monolayer comprise silicon terminated with chlorine, as shown in the right side of FIG. 1B. Those skilled in the art will recognize that the chlorine terminated silicon monolayer is merely illustrative and that other components may be present in the monolayer. The process chamber is purged to remove an residual unreacted HCD and reaction byproducts. Purging of the chamber may be needed to ensure that subsequent reactants can substantially only react with the substrate and/or the partial monolayer on the substrate and avoid gas phase reactions which may form unwanted surface products.

As shown in the reaction of FIG. 1C, water vapor is flowed to the substrate under conditions which form at least a partial monolayer on the substrate. The partial monolayer, as shown in the right side of FIG. 1C, is a SiO₂ monolayer. The process chamber is purged after this partial monolayer is formed.

A second atomic layer deposition process is performed. This process is shown in FIGS. 1D and 1E. The second atomic layer deposition process comprises flowing a silicon containing gas, shown as disilane, to the substrate within the chamber under conditions which form a partial monolayer comprising silicon. The partial monolayer, shown on the right side of FIG. 1D, is a combination of SiH₂ on the surface of the substrate 10 and SiH₂ on some of the SiO₂ formed in the first atomic layer deposition process. The process chamber is purged to remove any unreacted disilane and reaction by-products.

As shown in FIG. 1E, a nitrogen plasma is flowed to the substrate within the chamber under conditions to form a partial monolayer. As shown in the right side of FIG. 1E, the partial monolayer comprises silicon nitride and can be formed on one or more of the substrate surface and the at least partial monolayer formed during the first atomic layer deposition process. The process chamber is then purged again to remove unreacted materials and reaction by-products. As one skilled in the art would understand, the embodiment shown in FIGS. 1A through 1E are exemplary and should not be taken as limiting the scope of the invention. There will be additional by-products, cross-reactions and reaction mechanisms (including catalytic mechanisms) which are not shown in the drawings.

The first atomic layer deposition process and the second atomic layer deposition process can be repeated as many times as needed. In some embodiments, the second atomic layer deposition process occurs before the first atomic layer deposition process. Additionally, the first atomic layer deposition process can be performed multiple times before the second atomic layer deposition process is performed. Moreover, the second atomic layer deposition process can be performed multiple times before the first atomic layer deposition process is performed.

In some embodiments, a plasma system and a processing chamber or system which may be used during methods described here for depositing or forming silicon oxide/nitride materials include the TXZ® CVD, chamber available from Applied Materials, Inc., located in Santa Clara, Calif. Further disclosure of plasma systems and processing chambers is described in commonly assigned U.S. Pat. Nos. 5,846,332, 6,079,356, and 6,106,625. In other embodiments, a PE-ALD processing chamber or system which may be used during methods described here for depositing or forming silicon oxide/nitride materials is described in commonly assigned U.S. Ser. No. 12/494,901, filed on Jun. 30, 2009, published as United States patent application publication number 20100003406. An ALD processing chamber used in some embodiments described herein may contain a variety of lid assemblies. Other ALD processing chambers may also be used during some of the embodiments described herein and are available from Applied Materials, Inc. A detailed description of an ALD processing chamber may be found in commonly assigned U.S. Pat. Nos. 6,821,563, 6,878,206, 6,916,398, and 7,780,785. In another embodiment, a chamber configured to operate in both an ALD mode as well as a conventional CVD mode may be used to deposit silicon oxide/nitride materials is described in commonly assigned U.S. Pat. No. 7,204,886.

The ALD process provides that the processing chamber or the deposition chamber may be pressurized at a pressure within a range from about 0.01 Torr to about 80 Torr, for example from about 0.1 Torr to about 10 Torr, and more specifically, from about 0.5 Torr to about 2 Torr. Also, according to one or more embodiments, the chamber or the substrate may be heated to a temperature of less than about 600° C., for example, about 400° C. or less, such as within a range from about 200° C. to about 400° C., and in other embodiments less than about 300° C., less than about 200° C., or less than about 100° C., for example in the range of about 50° C. and 100° C., such as in the range of about 70° C. and 90° C. As will be understood by those skilled in the art, ALD reactions at low temperatures may benefit from the presence of a catalyst. Suitable catalysts include, but are not limited to, ammonia, pyridine and Lewis bases.

Reference throughout this specification to “one embodiment,” “certain embodiments,” “one or more embodiments,” “an embodiment,” “one aspect,” “certain aspects,” “one or more embodiments” and “an aspect” means that a particular feature, structure, material, or characteristic described in connection with the embodiment is included in at least one embodiment of the invention. Thus, the appearances of the phrases such as “in one or more embodiments,” “in certain embodiments,” “in one embodiment,” “in an embodiment,” “according to one or more aspects,” “in an aspect,” etc., in various places throughout this specification are not necessarily referring to the same embodiment or aspect of the invention. Furthermore, the particular features, structures, materials, or characteristics may be combined in any suitable manner in one or more embodiments or aspects. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. A method for forming a film on a substrate, the film having a refractive index and an absorption coefficient, the method comprising:
exposing the substrate sequentially to a first reactant gas comprising a first species including one or more of silicon, oxygen and nitrogen and a second reactant gas comprising a second species to form a first partial layer on the substrate during a first atomic layer deposition process;
exposing the substrate sequentially to a third reactant gas comprising a third species including one or more of silicon, oxygen and nitrogen and a fourth reactant gas comprising a fourth species to form a second partial layer on the substrate during a second atomic layer deposition process; and
repeating sequentially the first atomic layer deposition process and the second atomic layer deposition process to form a mixed film comprising the first partial layer and the second partial layer,
wherein one or more of the refractive index and the absorption coefficient can be altered by changing a ratio of the first partial layer to the second partial layer.

2. The method of claim 1, wherein either the first atomic layer deposition process or the second atomic layer deposition process occurs first.

3. The method of claim 1, wherein the mixed film comprises silicon oxide and silicon nitride and the refractive index of the mixed silicon oxide/silicon nitride film is in a range of about 1.6 to about 1.7.

4. The method of claim 1, wherein the first species comprises one or more of silane, disilane and a halide of silane.

5. The method of claim 1, wherein the second species comprises water.

6. The method of claim 1, wherein the third species comprises one or more of silane, disilane and a halide of silane.

7. The method of claim 6, wherein the fourth species comprises one or more of nitrogen and a reducing agent or oxidizing agent sufficient to form silicon.

8. The method of claim 7, wherein the nitrogen is a plasma.

9. The method of claim 8, wherein the second atomic layer deposition process is performed in a process chamber and the plasma is generated remotely from the process chamber.

10. The method of claim 8, wherein the second atomic layer deposition process is performed in a process chamber and the plasma is generated within the process chamber.

11. The method of claim 1, wherein the first atomic layer deposition process occurs at a temperature in a range of about 20° C. to about 150° C.

12. The method of claim 1, wherein the second atomic layer deposition process occurs at a temperature in a range of about 75° C. to about 500° C.

13. The method of claim 1, further comprising exposing the substrate to a purge gas during a purge process.

14. The method of claim 13, wherein the purge process occurs after one or more of the first atomic layer deposition process and the second atomic layer deposition process.

15. The method of claim 13, wherein the purge gas is selected from an inert gas.

16. The method of claim 15, wherein the inert gas is selected from nitrogen, argon and combinations thereof.

17. The method of claim 1, wherein the mixed film has a thickness up to about 500 Å.

18. The method of claim 1, wherein the first atomic layer deposition process forms less than a full monolayer of silicon oxide and the second atomic layer deposition process forms less than a full monolayer of one or more of silicon nitride and silicon creating a mixture of partial monolayers without distinct layers of silicon oxide and one or more of silicon nitride and silicon.

19. A method of forming a mixed film on a substrate, the method comprising:
(a) disposing a substrate within a processing chamber;
(b) performing a first atomic layer deposition process comprising:
(i) flowing hexachlorodisilane gas to at least a portion of the substrate within the chamber under conditions which form a partial monolayer on the substrate, the partial monolayer comprising silicon terminated with chlorine,
(ii) purging the hexachlorodisilane,
(iii) flowing water vapor to the substrate within the chamber under conditions which form a partial monolayer on the substrate, the partial monolayer comprising silicon oxide and
(iv) purging the water vapor;
(c) performing a second atomic layer deposition process comprising:
(i) flowing disilane gas to at least a portion of the substrate within the chamber under conditions which form a partial monolayer comprising silicon,
(ii) purging the disilane,
(iii) flowing one or more of a nitrogen plasma and a reductant to the substrate within the chamber under conditions to form a partial monolayer comprising one or more of silicon nitride and silicon,and
(iv) purging the one or more of nitrogen plasma and reductant; and
(d) repeating steps (b) and (c).

20. A method for forming a film on a substrate, the method comprising:
exposing the substrate sequentially to a first reactant gas comprising a silicon species and a second reactant gas comprising an oxygen species to form at least a partial layer of silicon oxide on the substrate during a first atomic layer deposition process;
exposing the substrate sequentially to a third reactant gas comprising a silicon species and a fourth reactant gas comprising a species to form at least a partial layer of one or more of silicon nitride and silicon on the substrate during a second atomic layer deposition process; and
repeating sequentially the first atomic layer deposition process and the second atomic layer deposition process to form one or more of a mixed silicon oxide/silicon nitride film or a mixed silicon oxide/silicon film, the film having a refractive index and absorption coefficient.
